(19) United States
(12) Patent Application Publication
(10) Pub. No.: US 2026/0342285 A1
(43) Pub. Date: Oct. 29, 2026

(54) SYSTEMS AND METHODS FOR THERMAL DROOP COMPENSATION FOR POWER AMPLIFIERS

(71) Applicant: Qorvo US, Inc., Greensboro, NC (US)

(72) Inventors: John Bellantoni, San Jose, CA (US); Michael Kevin O'Neal, Saratoga, CA (US)

(21) Appl. No.: 19/491,052

(22) PCT Filed: Apr. 30, 2024
(86) PCT No.: PCT/US2024/026978

§ 371 Date: Dec. 8, 2025

Related U.S. Application Data
(60) Provisional application No. 63/522,737, filed on Jun. 23, 2023.

(51) Int. Cl. H03F 1/30; H03F 1/02; H03F 3/195; H03F 3/213

(52) U.S. Cl. CPC H03F 1/30; H03F 1/0222; H03F 3/213; H03F 3/195; H03F 2200/447; H03F 2200/451; H03F 2200/468

(57) ABSTRACT

Systems and methods for thermal droop compensation for power amplifiers are disclosed. In one aspect, a current mirror that mirrors currents in transistors used in the power amplifier is added. The mirroring elements are embedded within the space occupied by the transistors used in the power amplifier. Based on this positioning, changes in temperature that occur in the transistors used in the power amplifier are nearly instantaneously experienced by the mirroring elements. Accordingly, changes in performance based on temperature are also experienced in the mirroring elements. The mirroring elements then provide an output signal that may be used to adjust an input signal or a bias signal provided to the transistors in the power amplifier. This adjustment effectively boosts the signal being amplified by the transistors in the power amplifier to offset thermally induced droop that otherwise would reduce the amplification provided by the power amplifier.

### RELATED APPLICATION

This application claims the benefit of U.S. provisional patent application Ser. No. 63/522,737, filed on Jun. 23, 2023, the disclosure of which is hereby incorporated herein by reference in its entirety.

### BACKGROUND

### I. Field of the Disclosure

The technology of the disclosure relates generally to power amplifiers operating at high pulse rates and ways to correct for thermally created gain droop.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find ways to increase the bandwidth available for wireless communication. This pressure has resulted in ever-faster wireless standards, which impose new requirements on power amplifiers associated with wireless transmitters. One such requirement is rapid switching and rapid power pulses, which in turn create waste heat in the power amplifiers. Such waste heat may negatively impact the performance of the power amplifiers. Compensating for the thermally induced performance variation provides room for innovation.

### SUMMARY

Aspects disclosed in the detailed description include systems and methods for thermal droop compensation for power amplifiers. In particular, aspects of the present disclosure contemplate adding a current mirror that mirrors currents in transistors used in the power amplifier. The mirroring elements are embedded within the space occupied by the transistors used in the power amplifier. Based on this positioning, changes in temperature that occur in the transistors used in the power amplifier are near instantaneously experienced by the mirroring elements. Accordingly, changes in performance based on temperature are also experienced in the mirroring elements. The mirroring elements then provide an output signal that may be used to adjust an input signal or a bias signal provided to the transistors in the power amplifier. This adjustment effectively boosts the signal being amplified by the transistors in the power amplifier to offset thermally induced droop that otherwise would reduce the amplification provided by the power amplifier. In this manner, expected behavior of the power amplifier is provided across rapid temperature variations improving overall performance.

In this regard, in one aspect, a power amplifier comprising is disclosed. The power amplifier includes an amplifying transistor, a current mirroring transistor physically proximate the amplifying transistor, and having a thermal path coupling the amplifying transistor and the current mirroring transistor. The power amplifier further includes a controller circuit coupled to the current mirror transistor and configured to adjust an input signal for the amplifying transistor to compensate for thermal droop.

In another aspect, a power amplifier is disclosed. The power amplifier includes an amplifier comprising a first amplifying transistor coupled to an input node and a second amplifying transistor cascoded with the first amplifying transistor and coupled to an output node. The power amplifier further includes a current mirror comprising a first mirroring transistor physically proximate the first amplifying transistor and a second mirroring transistor physically proximate the second amplifying transistor, wherein the current mirror generates a shared current signal and a controller circuit coupled to the current mirror and configured to receive the shared current signal and produce a control signal to adjust an input signal to the amplifier to compensate for temperature droop.

In another aspect, a method of compensating for thermal droop in a power amplifier is disclosed. The method includes positioning a current mirroring transistor physically proximate an amplifying transistor and positioning a second current mirroring transistor distant from the amplifying transistor. The method further includes generating a difference between currents in the current mirroring transistor and the second current mirroring transistor to generate a control signal and using the control signal to adjust an input signal for the amplifying transistor to compensate for thermal droop.

### BRIEF DESCRIPTION OF THE DRAWINGS

FIG. 1 is a hybrid block and circuit diagram of a power amplifier having a thermal droop compensation circuit working with a first cascoded transistor according to an exemplary aspect of the present disclosure;

FIG. 2 is a top plan view of a power amplifier die having cascoded amplifying transistors with embedded mirroring transistors embedded therein;

FIG. 3 is a hybrid block and circuit diagram of a power amplifier having a thermal droop compensation circuit working with a second cascoded transistor according to an exemplary aspect of the present disclosure;

FIG. 4 is a hybrid block and circuit diagram of a power amplifier having a thermal droop compensation circuit working with a previous stage of a power amplifier chain according to an exemplary aspect of the present disclosure;

FIG. 5 is a hybrid block and circuit diagram of the power amplifier of FIG. 4 coupled to a driver amplifier for droop compensation;

FIG. 6 is a hybrid block and circuit diagram of the power amplifier of FIG. 4 coupled to a variable attenuator for droop compensation;

FIG. 7 is a hybrid block and circuit diagram of a power amplifier without cascoded transistors with a thermal droop compensation circuit according to an exemplary aspect of the present disclosure;

FIG. 8 is a hybrid block and circuit diagram of a power amplifier without cascoded transistors with a thermal droop compensation circuit that operates to compensate using a driver amplifier;

FIG. 9 is a flow chart illustrating a process associated with the thermal droop compensation circuits according to aspects of the present disclosure; and

FIG. 10 is a block diagram of a transceiver, which may include the power amplifiers of FIGS. 1-8 according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include systems and methods for thermal droop compensation for power amplifiers. In particular, aspects of the present disclosure contemplate adding a current mirror that mirrors currents in transistors used in the power amplifier. The mirroring elements are embedded within the space occupied by the transistors used in the power amplifier. Based on this positioning, changes in temperature that occur in the transistors used in the power amplifier are near instantaneously experienced by the mirroring elements. Accordingly, changes in performance based on temperature are also experienced in the mirroring elements. The mirroring elements then provide an output signal that may be used to adjust an input signal or a bias signal provided to the transistors in the power amplifier. This adjustment effectively boosts the signal being amplified by the transistors in the power amplifier to offset thermally induced droop that otherwise would reduce the amplification provided by the power amplifier. In this manner, expected behavior of the power amplifier is provided across rapid temperature variations improving overall performance.

While aspects of the present disclosure are applicable to a variety of power amplifiers, power amplifiers based on gallium nitride (GaN) technologies are particularly situated to benefit from the teachings contained herein. Further, it should be noted that many of the control elements described in the present disclosure may occur outside a GaN and may be implemented in alternate technologies such as silicon. Still further, power amplifiers that rely on cascoded transistors may provide multiple ways to implement aspects of the present disclosure.

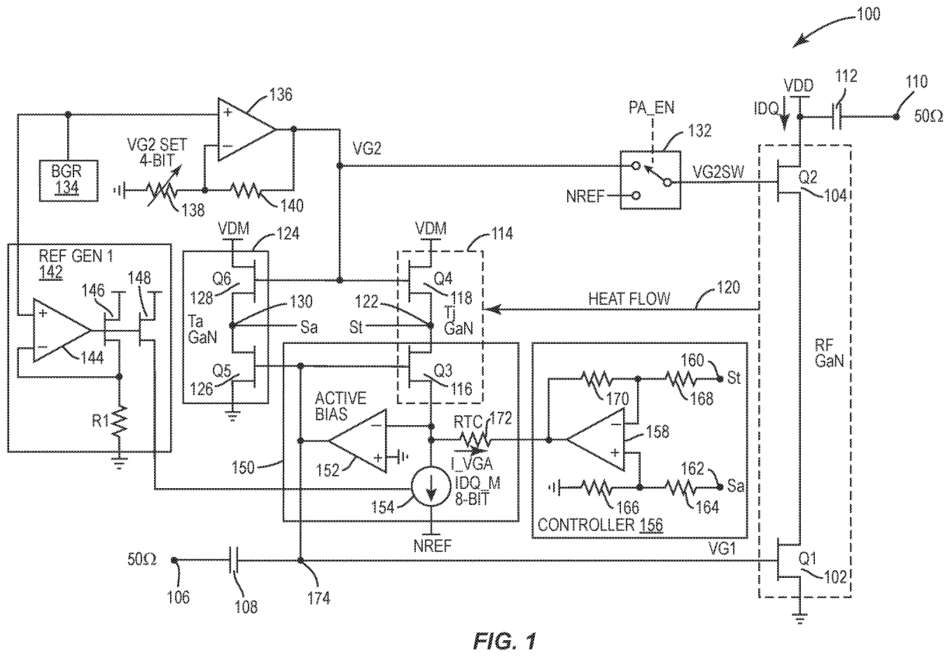

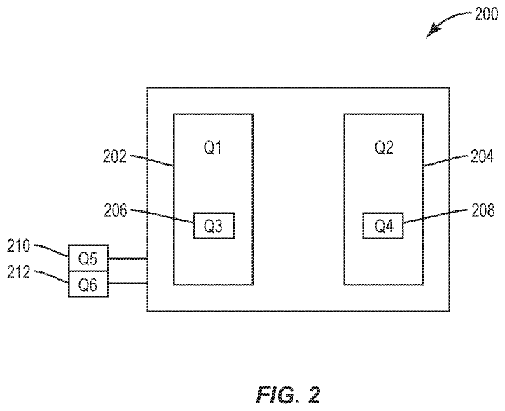

In this regard, FIG. 1 is a hybrid block and circuit diagram of a first power amplifier 100 with a first transistor (Q1) 102 and a cascoded output second transistor (Q2) 104. An input signal travels from an input node 106 through a blocking capacitor 108 to a gate of the first transistor 102. The second transistor 104 is coupled to the first transistor 102 and has an output node 110, which may also have a blocking capacitor 112. The output node 110 provides an amplified signal for subsequent transmission, such as through an antenna (not shown). A first current mirror 114 includes a third transistor (Q3) 116 and a fourth transistor (Q4) 118. The third transistor 116 is embedded in the first transistor 102, and the fourth transistor 118 is embedded in the second transistor 104. The concept of being embedded is discussed below with reference to FIG. 2.

With continued reference to FIG. 1, there is a thermal coupling indicated by heat flow path 120 between the transistors 102, 104 and the transistors 116, 118. As temperature in the transistors 102, 104 changes as a function of signal pulses, temperature will also change in the transistors 116, 118. The third transistor 116 and the fourth transistor 118 share a node 122 and provide a signal St at the node 122.

With continued reference to FIG. 1, a second current mirror 124 is formed from a fifth transistor (Q5) 126 and a sixth transistor (Q6) 128. The fifth transistor 126 and the sixth transistor 128 are spaced from the first transistor 102 and the second transistor 104 and effectively respond to an ambient temperature. A node 130 between the transistors 126, 128 provides an output signal Sa.

With continued reference to FIG. 1, a switch 132 allows changing between a transmit and a receive mode. That is, in a first position, the switch 132 couples a gate of the second transistor 104 to a reference value NREF and the device enters a receive mode. However, in a second position (and as shown), the switch couples the gate of the second transistor 104 to an input voltage VG2, and the device enters a transmit mode. VG2 is formed by a bandgap reference voltage 134 coupled to an operational amplifier (op-amp) 136. Feedback from the op-amp 136 is set by a fixed variable resistor 138 and a feedback resistor 140. The fixed variable resistor 138 is adjusted to a value to compensate for manufacturing variations and then fixed. This arrangement ensures that a constant VG2 is provided to the gate of the second transistor 104 in the transmit mode. Additionally, VG2 is provided to bias the fourth transistor 118 and the sixth transistor 128.

With continued reference to FIG. 1, the bandgap reference voltage 134 is also coupled to a reference generator 142. The reference generator 142 is formed from an op-amp 144 and transistors 146, 148. An output of the transistor 148 is used by an active bias circuit 150 that biases the third transistor 116 and the fifth transistor 126.

More specifically, the active bias circuit 150 may include an op-amp 152 and a current source 154. The op-amp 152 is coupled to the third transistor 116 at a negative input, while a positive input is coupled to a ground. The negative input is also coupled to a controller 156. The controller 156 includes an op-amp 158 and receives signal St at a first input node 160 and signal Sa at a second input node 162. The signal Sa is provided to a positive input of the op-amp 158 through a resistor 164. The positive input is also coupled to ground through a second resistor 166. The signal St is provided to a negative input of the op-amp 158 through a third resistor 168. A feedback resistor 170 couples the negative input of the op-amp 158 to the output of the op-amp 158.

In use, the op-amp 158 detects a difference between Sa and St, and as St rises above Sa, to keep the inputs equal, current is drawn through the feedback resistor 170, which generates a current I_VGA through an RTC resistor 172 coupled to the negative input of the op-amp 152 in the active bias circuit 150. This pull on the negative input of the op-amp 152 causes the output of the op-amp 152 to rise so that third transistor 116 provides sufficient current to provide I_VGA and keep the inputs of the op-amp 152 equal. When the output of the op-amp 152 rises, more current is provided at node 174 and the gate of the first transistor 102.

In this manner, a signal VG1 increases to compensate for thermal droop experienced in the first transistor 102 and the second transistor 104.

FIG. 2 is a top plan view of a power amplifier die 200, which may correspond to the power amplifier 100. The power amplifier die 200 has cascoded amplifying transistors 202, 204 (analogous to Q1 and Q2) with embedded mirroring transistors 206, 208 (analogous to Q3 and Q4) embedded therein. That is, the source, gate, and drains of the mirroring transistors 206, 208 are interleaved with elements of the amplifying transistors 202, 204. It should be appreciated that the mirroring transistors 206, 208 are a fraction (e/g., one-twentieth) of the size of the amplifying transistors 202, 204. While the mirroring transistors 206, 208 are embedded, ambient temperature transistors 210, 212 (analogous to Q5 and Q6) may be spaced from the amplifying transistors 202, 204 (and may even be off die).

While the term embedded is used to describe the position of the first transistor 102, 202 relative to the third transistor 116, 206 and the second transistor 104, 204 relative to the fourth transistor 118, 208, this term is not meant to be limiting. That is, modeling and experiments show that having the smaller transistors 116, 118 positioned within the structure of the larger transistors 102, 104 are effective at providing the tight thermal coupling between the transistors to measure thermal droop and generate a correction in a timely manner, it should be appreciated that there may be other positions which are sufficiently proximate to achieve the same short thermal path. At currently contemplated frequencies with currently contemplated pulses, to achieve optimal correction, the thermal path is less than ten microseconds and, in some cases, is less than five microseconds. Embedded transistors, as illustrated in FIG. 2, meet these parameters. Different technologies may relax this timing.

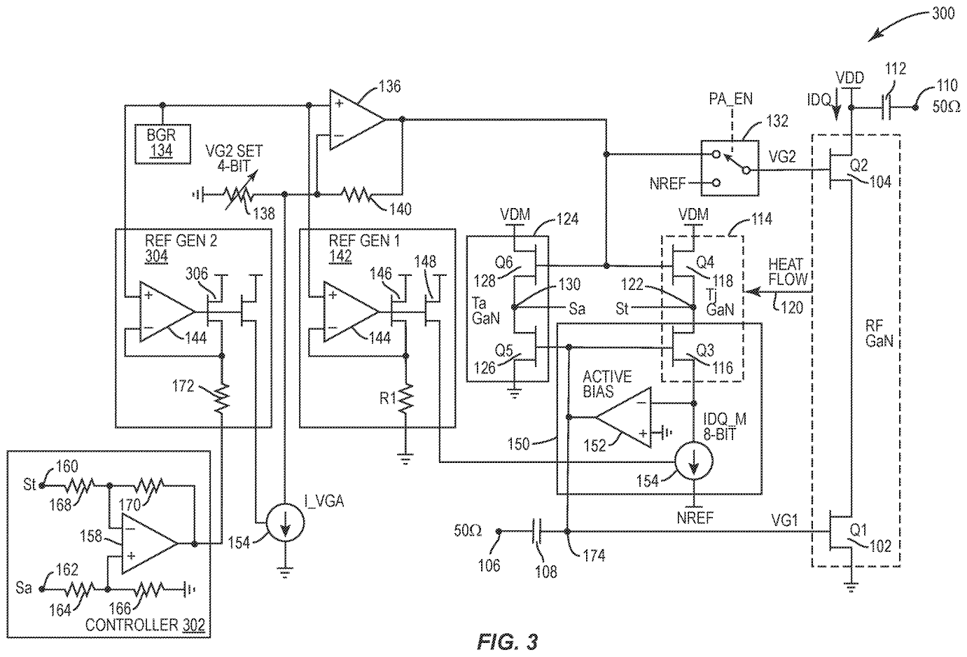

FIG. 3 is a hybrid block and circuit diagram of a power amplifier 300 having a thermal droop compensation circuit working with a second cascoded transistor according to an exemplary aspect of the present disclosure. More specifically, many of the elements of the power amplifier 300 are identical to the elements to the power amplifier 100 and thus share numbers. However, instead of working to raise VG1, the controller 302 is coupled to a second reference generator 304, which raises the positive input of the op-amp 136, thereby raising VG2. The principle of operation remains the same. When there is an imbalance at the op-amp 158, a current I_VGA is pulled through the RTC resistor 172, which creates an imbalance in an op-amp 306. The imbalance causes the current source 154 to generate more current to keep the inputs of the op-amp 306 equal. This current is added to the negative input of the op-amp 136, which raises VG2 to keep the inputs equal.

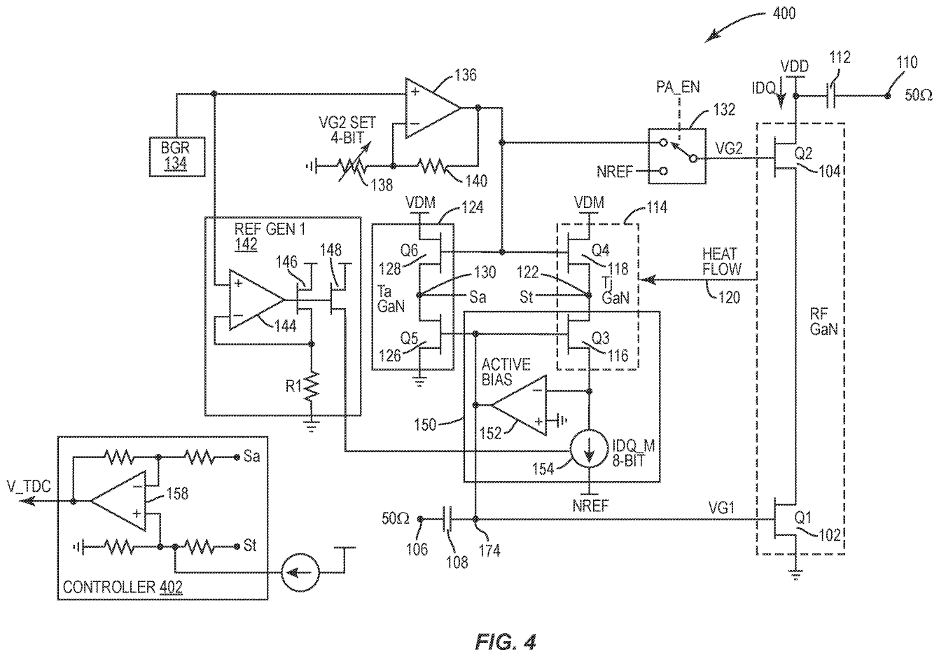

Instead of adjusting gate voltages of the cascode transistors Q1, Q2, it may also be possible to provide some form of upstream control. In this regard, FIG. 4 is a hybrid block and circuit diagram of a power amplifier 400 having a thermal droop compensation circuit working with a previous stage of a power amplifier chain according to an exemplary aspect of the present disclosure. As with power amplifiers 100 and 300, heat flow path 120 operates on the third transistor 116 and fourth transistor 118 to create St. Fifth and sixth transistors 124, 126 create Sa. St and Sa are provided to a controller 402, which generates a control signal V_TDC that may be used by an upstream element.

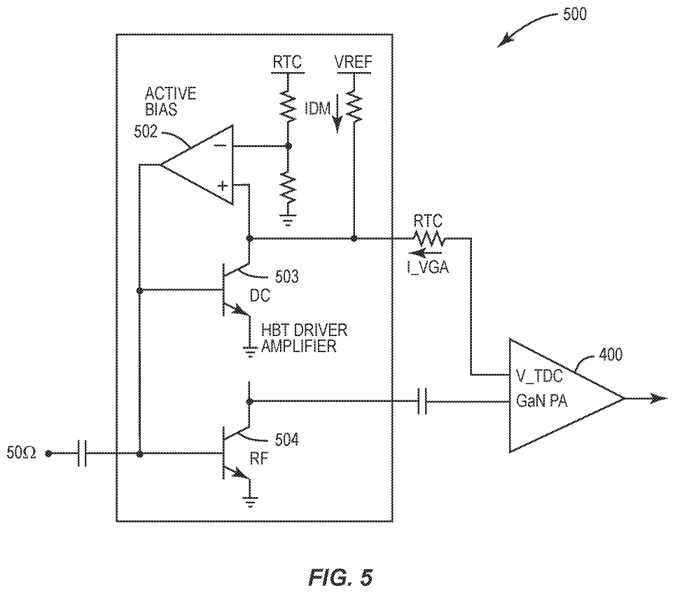

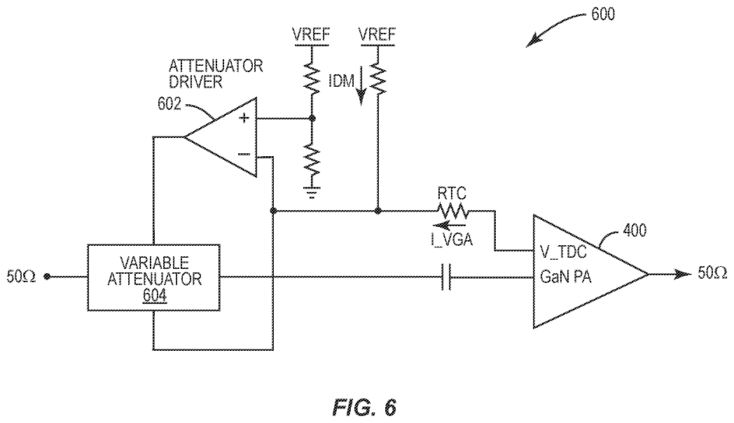

As illustrated in FIG. 5, the upstream element may be a driver amplifier 500, or as illustrated in FIG. 6, the upstream element may be a variable attenuator 600. With respect to FIG. 5, the driver amplifier 500 may be off-chip relative to the power amplifier 400 and may be a different technology, such as, for example, a bipolar junction transistor (BJT) or heterojunction bipolar transistor (HBT). As described above, the power amplifier 400 generates a current I_VGA, which, as illustrated, may pull on a positive input of an op-amp 502. The positive input is also coupled to a mirror transistor 503. A negative input of the op-amp 502 is held at a desired reference to support an active bias for a driver transistor 504. To keep the inputs balanced, the output of the op-amp 502 rises, and the signal generated at a collector of the driver transistor 504 rises to offset the thermal droop.

Similarly, in FIG. 6, the power amplifier 400 generates a current I_VGA, which, as illustrated, may pull on a negative input of an op-amp 602. The positive input of the op-amp 602 is fixed relative to Vref. To keep the inputs equal, the output of the op-amp changes and sends a signal to a variable attenuator 604. The variable attenuator 604 lowers attenuation of the signal provided to the negative input of the op-amp 602 and also to the power amplifier 400. This change in the signal provided to the power amplifier 400 offsets the thermal droop.

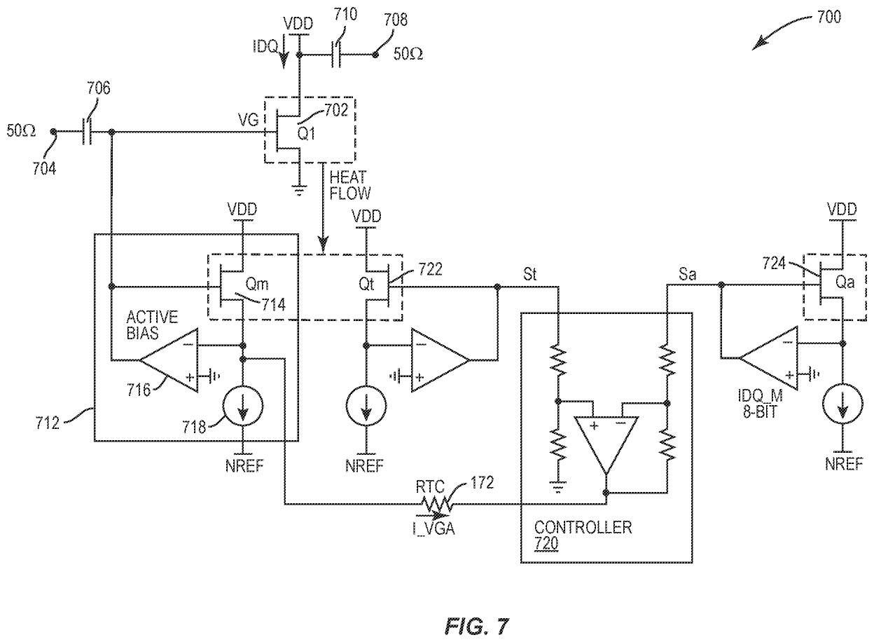

The above discussion has focused on a cascoded power amplifier. The present disclosure is not so limited and may work with a power amplifier having only a single amplifying transistor, as better illustrated in FIG. 7. Specifically, a power amplifier 700 may include an amplifying transistor (Q1) 702. A gate of the amplifying transistor 702 may be coupled to an input 704 through a blocking capacitor 706. An output 708 may also be coupled to the amplifying transistor 702 through a blocking capacitor 710. The gate may also be coupled to an active bias circuit 712, which may include a transistor (Qm) 714 that works with an op-amp 716 and a current source 718 to provide the active bias. That is, as temperature fluctuations on the transistor 714 change the current drawn from the current source 718 at the negative input of the op-amp 716, the output changes to keep the inputs equal, thereby also changing the bias signal provided at the gate of the amplifying transistor 702. The active bias circuit 712 also receives a current I_VGA generated by a controller 720.

As described above, I_VGA is generated responsive to a difference between Sa and St, where St is generated by a sensing transistor (Qt) 722 embedded in the amplifying transistor 702, and Sa is generated by an ambient transistor (Qa) 724 spaced from the amplifying transistor 702.

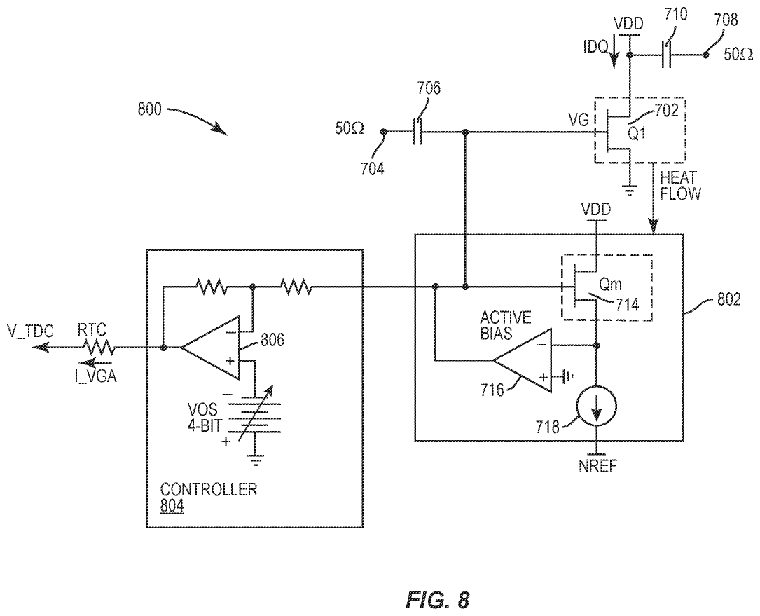

Instead of doing the compensation on-chip with the active bias circuit 712, it is also possible to pull the controller off-chip and manage the compensation at an upstream element, such as a driver amplifier or variable attenuator, as better seen in FIG. 8. Much of the power amplifier 800 is the same as power amplifier 700, but the active bias circuit 802 does not receive the additional input from the controller circuit. Instead, the output of the op-amp 716 is provided to a controller circuit 804, which controls an upstream element. Again, changes in the temperature in the amplifying transistor 702 change operation of the transistor 714, which changes the input of the op-amp 806 in the controller circuit 804. This change in the input of the op-amp 806 causes the output to change, generating I_VGA.

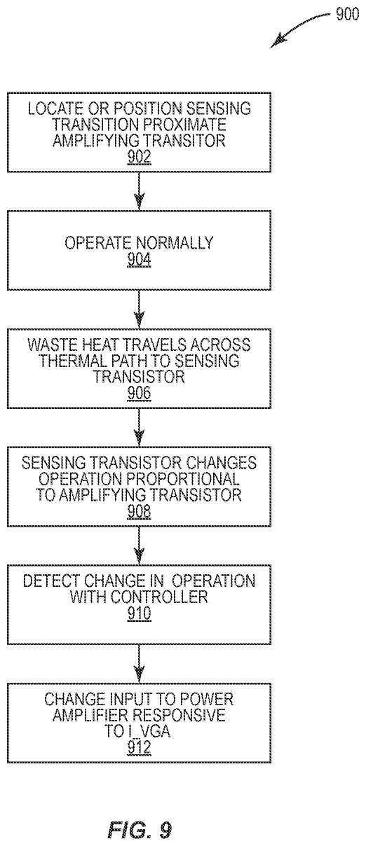

The general process 900 for compensating for thermal droop is illustrated by the flowchart of FIG. 9. The process 900 begins by locating a sensing transistor in close proximity to an amplifying transistor (block 902), such as embedding Q3 and Q4 or Qm/Qt in Q1 and/or Q2. The power amplifier operates normally (block 904) with power pulses that generate waste heat. The waste heat travels across a thermal path from the amplifying transistor to the sensing transistor (block 906). The sensing transistor changes operation based on the changes in temperature proportional to changes in the operation of the amplifying transistor (block 908). This change in the operation of the sensing transistor is detected at a controller circuit that generates I_ VGA responsive thereto (block 910). An input to the power amplifier is changed responsive to I_VGA to compensate for thermal droop (block 912).

The systems and methods of thermal droop compensation, according to aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

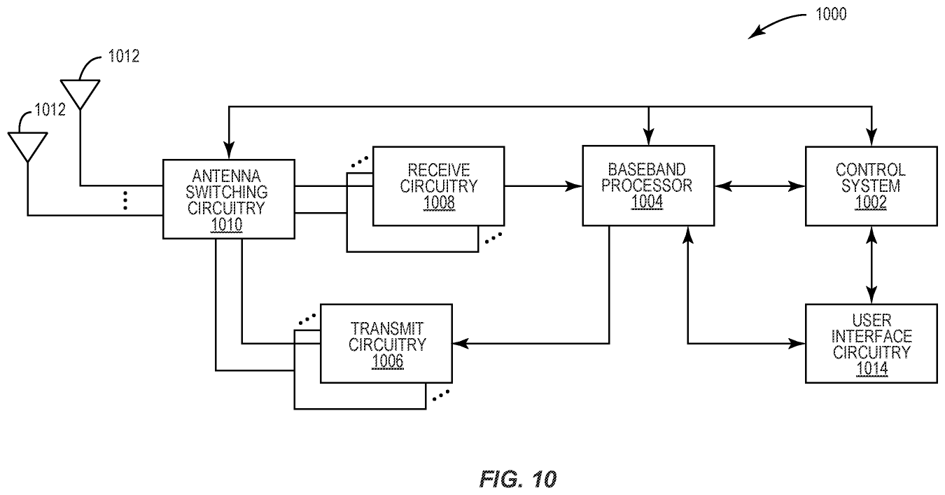

With reference to FIG. 10, the concepts described above may be implemented in various types of user elements 1000, such as mobile terminals, smart watches, tablets, computers, navigation devices, access points, and like wireless communication devices that support wireless communications, such as cellular, wireless local area network (WLAN), Bluetooth, and near field communications. The user elements 1000 will generally include a control system 1002, a baseband processor 1004, transmit circuitry 1006, which may include power amplifiers operating with thermal droop compensation according to aspects of the present disclosure, receive circuitry 1008, antenna switching circuitry 1010, multiple antennas 1012, and user interface circuitry 1014. In a non-limiting example, the control system 1002 can be a field-programmable gate array (FPGA) or an application-specific integrated circuit (ASIC), as an example. In this regard, the control system 1002 can include at least a microprocessor(s), an embedded memory circuit(s), and a communication bus interface(s). The receive circuitry 1008 receives radio frequency signals via the antennas 1012 and through the antenna switching circuitry 1010 from one or more base stations. A low noise amplifier and a filter of the receive circuitry 1008 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 1004 processes the digitized received signal to extract the information or data bits conveyed in the received signal. This processing typically comprises demodulation, decoding, and error correction operations. The baseband processor 1004 is generally implemented in one or more digital signal processors (DSPs) and ASICs.

For transmission, the baseband processor 1004 receives digitized data, which may represent voice, data, or control information, from the control system 1002, which it encodes for transmission. The encoded data is output to the transmit circuitry 1006, where a digital-to-analog converter(s) (DAC) converts the digitally encoded data into an analog signal, and a modulator modulates the analog signal onto a carrier signal that is at a desired transmit frequency or frequencies. A power amplifier, such as those described above, will amplify the modulated carrier signal to a level appropriate for transmission and deliver the modulated carrier signal to the antennas 1012 through the antenna switching circuitry 1010 to the antennas 1012. The multiple antennas 1012 and the replicated transmit and receive circuitries 1006, 1008 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

1. A power amplifier comprising:
an amplifying transistor;
a current mirroring transistor physically proximate the amplifying transistor, such that the current mirroring transistor is embedded in the amplifying transistor such that a gate, drain, and source of the current mirroring transistor are interleaved with elements of the amplifying transistor, and having a thermal path coupling the amplifying transistor and the current mirroring transistor; and
a controller circuit coupled to the current mirroring transistor and configured to adjust an input signal for the amplifying transistor to compensate for thermal droop.

2. (canceled)

3. The power amplifier of claim 1, wherein the amplifying transistor and the current mirroring transistor comprise gallium nitride (GaN) transistors.

4. The power amplifier of claim 1, further comprising a second amplifying transistor cascoded relative to the amplifying transistor.

5. The power amplifier of claim 4, wherein the amplifying transistor comprises an output for the power amplifier relative to the second amplifying transistor.

6. The power amplifier of claim 4, wherein the amplifying transistor comprises an input for the power amplifier relative to the second amplifying transistor.

7. The power amplifier of claim 1, further comprising a variable attenuator that adjusts a signal to create a signal on which the input signal is based and wherein the controller circuit is coupled to the variable attenuator.

8. The power amplifier of claim 1, further comprising a driver amplifier that creates the input signal and wherein the controller circuit is coupled to the driver amplifier.

9. The power amplifier of claim 1, wherein the controller circuit comprises a bipolar technology.

10. The power amplifier of claim 1, further comprising an active bias circuit coupled to the amplifying transistor.

11. A power amplifier comprising:
an amplifier comprising:
a first amplifying transistor coupled to an input node;
a second amplifying transistor cascoded with the first amplifying transistor and coupled to an output node;
a current mirror comprising:
a first mirroring transistor physically proximate the first amplifying transistor, such that the first mirroring transistor is embedded in the first amplifying transistor such that a gate, drain, and source of the first mirroring transistor are interleaved with elements of the first amplifying transistor; and
a second mirroring transistor physically proximate the second amplifying transistor;
wherein the current mirror generates a shared current signal; and
a controller circuit coupled to the current mirror and configured to receive the shared current signal and produce a control signal to adjust an input signal to the amplifier to compensate for temperature droop.

12. The power amplifier of claim 11, further comprising an ambient temperature sensor comprising a second current mirror spaced from the amplifier and configured to generate an ambient current signal provided to the controller circuit.

13. The power amplifier of claim 12, wherein the controller circuit is configured to use a difference between the ambient current signal and the shared current signal to generate the control signal.

14. The power amplifier of claim 13, further comprising a variable attenuator coupled to the controller circuit and the input node.

15. The power amplifier of claim 13, further comprising a driver amplifier coupled to the controller circuit and the input node.

16. The power amplifier of claim 13, further comprising an active bias circuit coupled to the input node and the controller circuit.

17. The power amplifier of claim 11 integrated into a device selected from the group consisting of: a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

18. A method of compensating for thermal droop in a power amplifier comprising:
positioning a current mirroring transistor physically proximate an amplifying transistor, such that the current mirroring transistor is embedded in the amplifying transistor such that a gate, drain, and source of the current mirroring transistor are interleaved with elements of the amplifying transistor;
positioning a second current mirroring transistor distant from the amplifying transistor;
generating a difference between currents in the current mirroring transistor and the second current mirroring transistor to generate a control signal; and
using the control signal to adjust an input signal for the amplifying transistor to compensate for thermal droop.

19. The method of claim 18, wherein using the control signal comprises using the control signal in an active bias circuit.

20. The method of claim 18, wherein using the control signal comprises using the control signal in a driver amplifier.
